(19) United States
(12) Patent Application Publication
(10) Pub. No.: US 2026/0165166 A1
(43) Pub. Date: Jun. 11, 2026

(54) CHIP PACKAGING BODY

(71) Applicant: SHENNAN CIRCUITS CO.,LTD., SHENZHEN (CN)

(72) Inventors: KAI ZHU, SHENZHEN (CN); ZEDONG WANG, SHENZHEN (CN); JUN WU, SHENZHEN (CN)

(21) Appl. No.: 19/417,209

(22) Filed: Dec. 11, 2025

Related U.S. Application Data
(63) Continuation of application No. PCT/CN2025/089650, filed on Apr. 17, 2025.

(30) Foreign Application Priority Data
Dec. 9, 2024 (CN) 202411807650.7

(51) Int. Cl. H10W 70/65; H10W 70/68; H10W 74/10

(52) U.S. Cl. CPC H10W 70/65; H10W 70/682; H10W 74/114

(57) ABSTRACT

A chip packaging body includes a base circuit board, at least one chip unit, a plastic encapsulation layer, and multiple connection members. A chip of each chip unit is connected to a first surface of a corresponding metal substrate. The plastic encapsulation layer is disposed on the first surface of the base circuit board. An end of each connection member is connected to a corresponding electrode of the chip, and another end of each connection member extends to a first surface of the plastic encapsulation layer for exposure. The multiple connection members include a first connection member, an end of the first connection member is connected to a side surface of the metal substrate. Another end of the first connection member extends to a board edge area, and then vertically extends to a side of the plastic encapsulation layer away from the base circuit board for exposure.

### CROSS-REFERENCE TO RELATED APPLICATIONS

The present application is a continuation of International Patent Application No. PCT/CN 2025/089650, filed on Apr. 17, 2025, which claims priority to Chinese Patent Application No. 202411807650.7, filed on Dec. 9, 2024, both of which are herein incorporated by reference in their entirety.

### TECHNICAL FIELD

The present disclosure relates to the technical field of chip packaging, and in particular to a chip packaging body.

### BACKGROUND

As global energy transition continues to advance, electrical energy has become an increasingly important energy form. A power chip is characterized by high conversion efficiency. However, a packaging method in related art has an excessive parasitic parameter, which affects switching frequency of the power chip.

Embedding the power chip into a printed circuit board has become one of the optimal solutions to reduce an integration parameter.

However, after embedding the power chip into the printed circuit board, connection members of the chip require internal electrical insulation, so as to prevent leakage or electrical breakdown between different transmission networks. The internal electrical insulation requires a certain amount of space, which is easy to conflict with internal wiring of the chip packaging body.

### SUMMARY OF THE DISCLOSURE

In order to solve the technical problem, the present disclosure provides a chip packaging body including a base circuit board, at least one chip unit, a plastic encapsulation layer, and a plurality of connection members. The base circuit board defines at least one mounting through-groove. The at least one chip unit is disposed in a corresponding mounting through-groove, each chip unit includes at least one metal substrate and at least one chip, each chip is connected to a first surface of a corresponding metal substrate, a second surface of the metal substrate is flush with a second surface of the base circuit board, and the second surface of the base circuit board is opposite to a first surface of the base circuit board. The plastic encapsulation layer is disposed on the first surface of the base circuit board, and the plastic encapsulation layer completely fills a gap between the base circuit board and the at least one chip unit. An end of each connection member is connected to a corresponding electrode of the chip, and another end of each connection member extends to a first surface of the plastic encapsulation layer for exposure. The plurality of connection members include a first connection member, an end of the first connection member is connected to a side surface of the metal substrate, so that the first connection member is connected to the chip; and another end of the first connection member extends along the second surface of the base circuit board to a board edge area, and then vertically extends to a side of the plastic encapsulation layer away from the base circuit board for exposure.

In some embodiments, the first connection member includes a first extension member and a first vertical member that are connected in sequence. An end of the first extension member is connected to the side surface of the metal substrate, and another end of the first extension member extends along the second surface of the base circuit board to the board edge area. The first vertical member is disposed in the board edge area, an end of the first vertical member is connected to the another end of the first extension member, and another end of the first vertical member vertically extends to the side of the plastic encapsulation layer away from the base circuit board for exposure.

In some embodiments, the plastic encapsulation layer includes a filling layer, a first layer, and a second layer; the filling layer is disposed in the mounting through-groove. The second layer is disposed on the first surface of the base circuit board, and the first layer is disposed on a surface of the second layer away from the base circuit board.

In some embodiments, the first vertical member includes a first conduction member, a second connection hole, and a first connection hole that are connected in sequence. The first conduction member is disposed in the base circuit board, the first connection hole is disposed in the first layer, and the second connection hole is disposed in the second layer. An end of the first conduction member is connected to the another end of the first extension member, another end of the first conduction member is connected to an end of the second connection hole, and an end of the first connection hole away from the second connection hole is exposed on a side of the first layer away from the base circuit board.

In some embodiments, the plurality of connection members further include a second connection member. The second connection member includes a cross member, a second extension member, and a second vertical member that are connected in sequence. An end of the cross member is connected to a first surface of the chip, and another end of the cross member extends on the surface of the second layer away from the base circuit board to reach the first surface of the base circuit board. An end of the second extension member is connected to the another end of the cross member, and another end of the second extension member extends along the first surface of the base circuit board to the board edge area. The second vertical member is disposed in the plastic encapsulation layer and disposed in the board edge area, an end of the second vertical member is connected to the another end of the second extension member, and another end of the second vertical member passes through the second layer and the first layer, until the another end of the second vertical member is exposed on the first surface of the plastic encapsulation layer.

In some embodiments, the plurality of connection members further include a second connection member. The second connection member includes a cross member, a second conduction member, a third extension member, and a third vertical member that are connected in sequence. An end of the cross member is connected to a first surface of the chip, and another end of the cross member extends on the surface of the second layer away from the base circuit board to reach the first surface of the base circuit board. The second conduction member is disposed in the base circuit board, an end of the second conduction member is connected to the another end of the cross member on the first surface of the base circuit board, and another end of the second conduction member vertically extends to the second surface of the base circuit board. The third extension member is disposed on the second surface of the base circuit board, an end of the third extension member is connected to the another end of the second conduction member, and another end of the third extension member extends along the second surface of the base circuit board to the board edge area. The third vertical member is disposed in the base circuit board, the second layer, and the first layer, an end of the third vertical member is connected to the another end of the third extension member in the board edge area of the second surface of the base circuit board, and another end of the third vertical member vertically extends to a side of the first layer away from the second layer for exposure.

In some embodiments, the plurality of connection members further include a third connection member. The third connection member is disposed in the first layer and the second layer, an end of the third connection member is connected to a first surface of the chip, and another end of the third connection member is exposed on a side of the first layer away from the second layer.

In some embodiments, the chip packaging body further includes a conductive trace. A layout area of the conductive trace includes one or more selected from the group consisting of the surface of the second layer away from the base circuit board, a surface of the first layer away from the base circuit board, and the first surface of the base circuit board. The conductive trace is connected to the third connection member, and a distance between the conductive trace and each of other connection members is greater than 0.3 millimeters.

In some embodiments, the chip packaging body further includes a heat dissipation device. The heat dissipation device is disposed on the second surface of the base circuit board, and the heat dissipation device includes an insulation plate and a heat sink; the insulation plate is disposed on the second surface of the base circuit board, and the heat sink is disposed on a surface of the insulation plate away from the base circuit board.

In some embodiments, the insulation plate includes a first metal layer, an insulation layer, and a second metal layer that are stacked in sequence; and the second metal layer is disposed on a surface of the heat sink close to the metal substrate. The first metal layer is disposed on the second surface of the base circuit board and the second surface of the metal substrate. A length of a connection path between a side surface of the first metal layer and a side surface of the heat sink is greater than 0.3 millimeters.

In some embodiments, the second connection hole is connected to the first conduction member in a staggered manner, and a displacement member is connected to an end of the second connection hole away from the first layer and an end of the first conduction member away from the first extension member.

In some embodiments, the third connection member includes a ninth connection hole and a tenth connection hole that are stacked, an end of the ninth connection hole is connected to a gate electrode on the first surface of the chip, and an end of the tenth connection hole away from the ninth connection hole is exposed on the first layer.

In some embodiments, the heat sink includes a protruding heat dissipation structure and a main body plate, the main body plate is disposed on a surface of the insulation plate away from the second surface of the base circuit board, and the protruding heat dissipation structure is disposed on a surface of the main body plate away from the insulation plate.

In some embodiments, a shape of the protruding heat dissipation structure is one or more selected from the group consisting of columnar-type, corrugated-type, series-connected-plate-type, and finned-type.

In some embodiments, a thickness of each of the first metal layer and the second metal layer ranges from 0.01 millimeters to 1.00 millimeter.

In some embodiments, the insulation layer includes a ceramic layer and/or a resin layer; and the insulation layer is the ceramic layer, and a thickness of the ceramic layer is greater than 0.05 millimeters; or the insulation layer is the resin layer, and a thickness of the resin layer is greater than 0.3 millimeters.

In some embodiments, a thickness of each of a trace and the plurality of connection members disposed on the first surface of the base circuit board is greater than or equal to 100 microns.

The present disclosure provides a chip packaging body including a base circuit board, at least one chip unit, a plastic encapsulation layer, and a plurality of connection members. The base circuit board defines at least one mounting through-groove. The at least one chip unit is disposed in a corresponding mounting through-groove, each chip unit includes at least one metal substrate and at least one chip, each chip is connected to a first surface of a corresponding metal substrate, a second surface of the metal substrate is flush with a second surface of the base circuit board, and the second surface of the base circuit board is opposite to a first surface of the base circuit board. The plastic encapsulation layer is disposed on the first surface of the base circuit board. An end of each connection member is connected to a corresponding electrode of the chip, and another end of each connection member extends to a first surface of the plastic encapsulation layer for exposure. The plurality of connection members include a first connection member, an end of the first connection member is connected to a side surface of the metal substrate, so that the first connection member is connected to the chip; and another end of the first connection member extends along the second surface of the base circuit board to a board edge area, and then vertically extends to a side of the plastic encapsulation layer away from the base circuit board for exposure.

### BRIEF DESCRIPTION OF THE DRAWINGS

FIG. 1 is a structural schematic view of a first embodiment of a chip packaging body provided in the present disclosure.

FIG. 2 is a structural schematic view of a second embodiment of the chip packaging body provided in the present disclosure.

FIG. 3 is an enlarged structural schematic view of a first connection member of FIG. 2.

FIG. 4 is an enlarged structural schematic view of a second connection member of FIG. 2.

FIG. 5 is a structural schematic view illustrating a partial structure between a metal substrate and a heat dissipation device.

FIG. 6 is a structural schematic view of a third embodiment of the chip packaging body provided in the present disclosure.

FIG. 7 is a structural schematic view of a fourth embodiment of the chip packaging body provided in the present disclosure.

FIG. 8 is an enlarged structural schematic view of the second connection member of FIG. 7.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

It should be noted that if directional indications (such as up, down, left, right, front, rear, or the like) are involved in some embodiments of the present disclosure, the directional indications are only configured to explain a relative position relationship between components in a specific posture (as shown in the accompanying drawings), a motion situation between the components in the specific posture (as shown in the accompanying drawings), or the like. In a case where the specific posture is changed, the directional indication is also changed accordingly.

In addition, if descriptions of “first”, “second”, and the like are involved in some embodiments of the present disclosure, the descriptions of “first”, “second”, and the like are only configured to describe and cannot be understood as indicating or implying relative importance or implicitly indicating the quantity of technical features indicated. Therefore, features that are defined as “first”, “second”, and the like may explicitly or implicitly include at least one of these features. In addition, the technical solutions between various embodiments can be combined with each other, but the combination must be able to be implemented by those of ordinary skill in the art. In a case where the combination of the technical solutions is contradictory or cannot be implemented, it should be considered that this combination of the technical solutions does not exist and is not within protection scope required by the present disclosure.

The present disclosure provides a chip packaging body, so as to solve a compatibility problem between internal electrical insulation settings and internal wiring in the chip packaging body.

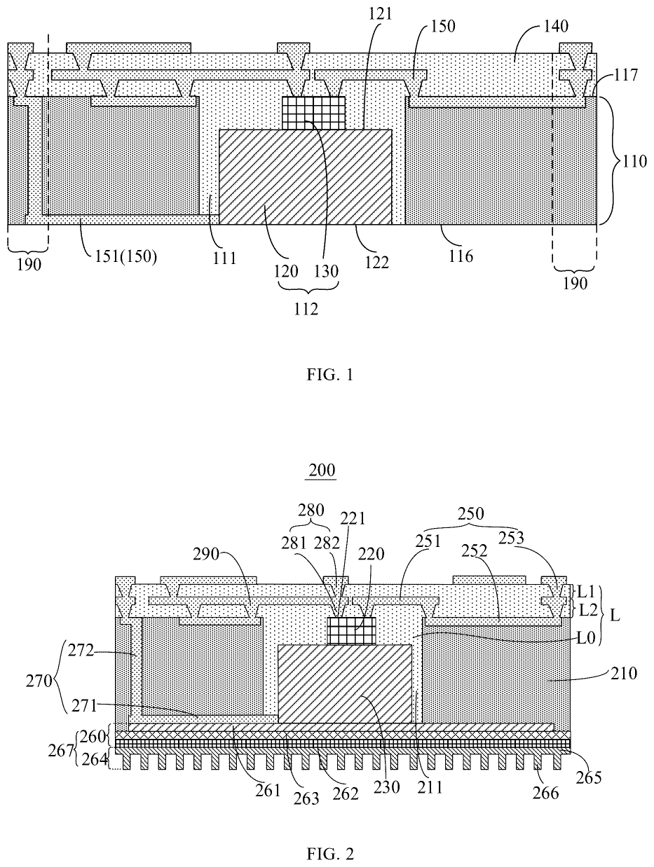

As illustrated in FIG. 1, FIG. 1 is a structural schematic view of a first embodiment of a chip packaging body provided in the present disclosure.

A chip packaging body 100 of the present embodiment includes a base circuit board 110, at least one chip unit 112, a plastic encapsulation layer 140, and multiple connection members 150.

The base circuit board 110 is a printed circuit board (PCB) with a pre-prepared circuit structure. The base circuit board 110 serves as a basic framework for embedding a chip 130. Traces of the base circuit board 110 have been patterned. The base circuit board 110 may be a multi-layer board with through-hole interconnection only, or a high density interconnector (HDI) board that includes blind hole interconnection. A specific structure of the base circuit board 110 is set based on actual needs (not illustrated in the figures). At least one mounting through-groove 111 is defined on the base circuit board 110, and the number of the mounting through-grooves 111 corresponds to the number of the chip units 112.

The chip unit 112 is fixedly disposed in a corresponding mounting through-groove 111. The chip unit 112 includes at least one metal substrate 120 and at least one chip 130. The chip 130 may include a power chip, such as an insulated-gate bipolar transistor (IGBT) or a metal-oxide semiconductor field-effect transistor (MOSFET). The chip 130 may also be other devices, such as a diode, an electronic tube, an electromechanical component, etc., which is not limited here. A material of the metal substrate 120 may be copper, molybdenum copper, tungsten copper, etc., so as to provide thermal and electrical conduction for the chip 130. A coefficient of thermal expansion (CTE) of the metal substrate 120 ranges from 5 ppm/° C. to 20 ppm/° C. A range of the coefficient of thermal expansion of the metal substrate 120 matches that of the chip 130, which can maintain structural stability between the chip 130 and the metal substrate 120 during thermal expansion. This can reduce stress caused by thermal expansion differences, thereby improving connection stability between the chip 130 and the metal substrate 120.

The chip packaging body 100 may include multiple chip units 112, and one chip unit 112 may include multiple chips 130, with specific settings based on actual needs.

The chip unit 112 is fixedly disposed in the corresponding mounting through-groove 111. One or more chip units 112 may be disposed on one base circuit board 110. A first surface 117 of the base circuit board 110, a first surface 121 of the metal substrate 120, and a first surface of the chip 130 are all disposed on the same side.

The chip 130 is fixedly connected to the first surface 121 of the metal substrate 120. In some embodiments, the first surface 121 of the metal substrate 120 is a planar surface. A second surface 122 of the metal substrate 120 is flush with a second surface 116 of the base circuit board 110, and the second surface 116 of the base circuit board 110 is a surface that is opposite to the first surface 117 of the base circuit board 110. The first surface of the chip 130 is flush with the first surface 117 of the base circuit board 110, so that the connection member 150 can lead out a signal from the first surface of the chip 130. The term “flush” in the present embodiment does not require absolute flushness. In practice, a tolerance within ±20% is acceptable.

The plastic encapsulation layer 140 is attached to the first surface 117 of the base circuit board 110. The plastic encapsulation layer 140 fills a gap between the base circuit board 110 and the at least one chip unit 112 for insulation encapsulation and device fixation. The plastic encapsulation layer 140 includes but is not limited to one or more insulation materials, such as an epoxy resin-based material, a polyester resin (PET), polyimide, a polyimide-based material, polycarbonate (PC), a bismaleimide triazine (BT)-based material, Ajinomoto build film (ABF), a flame retardant 4 (FR4) resin, a ceramic-based material, etc.

An end of each connection member 150 is respectively connected to a corresponding electrode of the chip 130, and another end of each connection member 150 extends to a side of the plastic encapsulation layer 140 for exposure, so as to lead out the signal of the chip 130 to the outside.

The connection members 150 include a first connection member 151. An end of the first connection member 151 is connected to the second surface 122 of the metal substrate 120, so that the first connection member 151 is connected to the chip 130. In some embodiments, the first connection member 151 is disposed on a side surface of the metal substrate 120 and close to the second surface 122 of the metal substrate 120. Another end of the first connection member 151 extends along the second surface 116 of the base circuit board 110 to the board edge area 190, and then vertically extends to the side of the plastic encapsulation layer 140 away from the base circuit board 110 for exposure. The board edge area 190 is an area with a certain width at an edge of entire chip packaging body 100. The connection member 150 is located in the board edge area 190, which does not mean that the connection member 150 is exposed outside the edge. The board edge area 190 surrounds periphery of the chip packaging body 100.

In the chip packaging body 100, it needs to lead out the signal of the chip 130 to the board edge area 190, so that an external device is connected. However, the chip packaging body 100 may include multiple chips 130. In a case where the signals of multiple chips 130 are led to the board edge area 190, horizontal wiring is often required, and the horizontal wiring can easily cause wiring conflicts with other conductive traces inside the chip packaging body 100. Therefore, in the present embodiment, the first connection member 151 is disposed on the second surface 122 of the metal substrate 120, and an electrode signal of the second surface of the chip 130 is led out from below. The signal is transmitted to the board edge area 190 and then vertically led to an edge of the surface of the plastic encapsulation layer 140 away from the base circuit board 110, so that a side of the first connection member 151 close to the plastic encapsulation layer 140 has a larger space for routing a conductive trace and increasing insulation distances between the first connection member 151 and other connection networks.

The second surface 116 of the base circuit board 110 may be provided with an insulation layer by pressing, or the second surface 116 of the base circuit board 110 may be provided with other insulation structures, so that the metal substrate 120 and the first connection member 151 are all insulated from an external environment, which is not limited here.

Through the above structure, in the chip packaging body of the present embodiment, the end of the first connection member is connected to the second surface of the metal substrate, so that the first connection member is connected to the chip. Another end of the first connection member extends along the second surface of the base circuit board to the board edge area, and then vertically extends to the side of the plastic encapsulation layer away from the base circuit board for exposure. Therefore, while the electrode signal of the second surface of the chip is led out through the first connection member, the side of the first connection member close to the plastic encapsulation layer has a larger space for routing the conductive traces and increasing the insulation distances between the first connection member and other connection networks, so as to increase wiring flexibility of the chip packaging body. The present disclosure provides a connection structure that is compatible with both internal electrical insulation and internal wiring of the connection members of the chip packaging body.

As illustrated in FIG. 2, FIG. 2 is a structural schematic view of a second embodiment of the chip packaging body provided in the present disclosure.

The positions and the connection relationships between the base circuit board 210, at least one chip unit, a plastic encapsulation layer L, and multiple connection members of a chip packaging body 200 in the present embodiment are the same as those in the previous embodiment.

In some embodiments, a first connection member 270 includes a first extension member 271 and a first vertical member 272 that are connected in sequence.

An end of the first extension member 271 is connected to the second surface of the metal substrate 230, and another end of the first extension member 271 extends along the second surface of the base circuit board 210 to the board edge area. The directions and the positions of the first surface, the second surface, and the board edge area of the present embodiment are similar to those in the previous embodiments, which are not repeated.

The first vertical member 272 is located in the board edge area, and an end of the first vertical member 272 is connected to another end of the first extension member 271. Another end of the first vertical member 272 vertically extends to a side of the plastic encapsulation layer L away from the base circuit board 210 for exposure.

In the above structure, the signal of the second surface of the chip 220 is transmitted to the second surface of the metal substrate 230 through the metal substrate 230. Then the signal is horizontally led to the board edge area through the first extension member 271. And then, in the board edge area, the signal is led upward through the first vertical member 272 to the side of the plastic encapsulation layer L away from the base circuit board 210 for exposure, thereby facilitating external connection. Due to this structure of the connection member, a side of the first connection member 270 close to the plastic encapsulation layer L can provide a larger space for routing a conductive trace 290 and increasing the insulation distances between the first connection member 270 and other connection networks.

In some embodiments, the plastic encapsulation layer L includes a filling layer L0, a first layer L1, and a second layer L2. The filling layer L0 is disposed inside a mounting through-groove 211 to fill the gap between the mounting through-groove 211 and the chip unit. The second layer L2 is stacked and attached to the first surface of the base circuit board 210, and the first layer L1 is stacked and attached to a surface of the second layer L2 away from the base circuit board 210. The filling layer L0, the first layer L1, and the second layer L2 are integrated after compression.

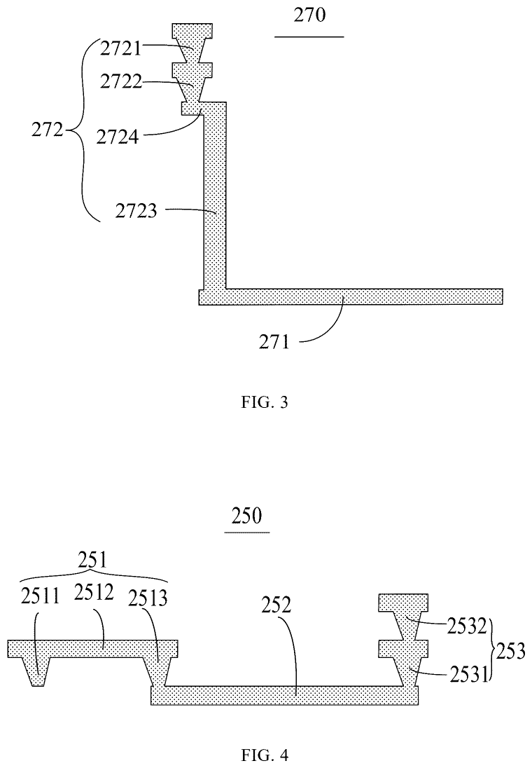

As illustrated in FIG. 3, FIG. 3 is an enlarged structural schematic view of a first connection member of FIG. 2.

In some embodiments, the first vertical member 272 includes a first conduction member 2723, a second connection hole 2722, and a first connection hole 2721 that are connected in sequence.

The first conduction member 2723 is disposed in the base circuit board 210, the first connection hole 2721 is defined in the first layer L1, and the second connection hole 2722 is defined in the second layer L2.

An end of the first conduction member 2723 is connected to another end of the first extension member 271, and another end of the first conduction member 2723 is connected to an end of the second connection hole 2722. An end of the first connection hole 2721 away from the second connection hole 2722 is exposed on a side of the first layer L1 away from the base circuit board 210.

In some embodiments, the second connection hole 2722 may be connected to the first conduction member 2723 in a staggered manner. That is, a displacement member 2724 is connected to an end of the second connection hole 2722 away from the first layer L1 and an end of the first conduction member 2723 away from the first extension member 271. In some embodiments, the second connection hole 2722 may also be vertically connected to the first conduction member 2723, and the displacement member 2724 may be omitted. A specific setting is based on a process or actual needs.

The first conduction member 2723 in the present embodiment is a metalized through-hole defined in the base circuit board 210. The second connection hole 2722 is a metalized blind hole defined in the second layer L2, and the first connection hole 2721 is a metalized blind hole defined in the first layer L1, with corresponding electrical conductivity. If the first layer L1 and the second layer L2 are laminated in a single pressing, the metalized blind holes in the first layer L1 and the second layer L2 cannot be completely filled by electroplating due to excessive thickness in the single pressing. Therefore, dual-setting of the first layer L1 and the second layer L2, and double stacked-hole design corresponding to the second connection hole 2722 and the first connection hole 2721, are adopted to simultaneously ensure a thickness of the plastic encapsulation layer L on the first surface of the base circuit board 210 and the electrical conductivity of the first vertical member 272.

In some embodiments, the connection members further include a second connection member 250. The second connection member 250 includes a cross member 251, a second extension member 252, and a second vertical member 253 that are connected in sequence.

An end of the cross member 251 is connected to the first surface of the chip 220, specifically connected to a transmission electrode on the first surface of the chip 220. Another end of the cross member 251 extends on a side of the second layer L2 away from the base circuit board 210, so as to reach the first surface of the base circuit board 210. The cross member 251 is configured to transmit the signal of the transmission electrode on the first surface of the chip 220 to the first surface of the base circuit board 210.

An end of the second extension member 252 is connected to another end of the cross member 251, and another end of the second extension member 252 extends along the first surface of the base circuit board 210 to the board edge area. The second extension member 252 is configured to transmit the signal of the transmission electrode on the first surface of the chip 220 to the edge of the first surface of the base circuit board 210.

The second vertical member 253 is disposed in the board edge area in the plastic encapsulation layer L. An end of the second vertical member 253 is connected to another end of the second extension member 252. Another end of the second vertical member 253 passes through the second layer L2 and the first layer L1, until the another end of the second vertical member 253 is exposed on the first surface of the plastic encapsulation layer L. The second vertical member 253 is configured to vertically transmit the signal of the edge of the first surface of the base circuit board 210 to an outer edge of the first layer L1 for external connection.

An end of the second connection member 250 away from the chip 220 horizontally extends on a side of the second layer L2 away from the base circuit board 210 to the first surface of the base circuit board 210. Therefore, a distance between this part of the second connection member 250 and the first surface of the metal substrate 230 is equal to the sum of a thickness of the second layer L2 and a thickness of the filling layer L0, thereby widening the distance between the second connection member 250 and the metal substrate 230. The second connection member 250 is insulated from the metal substrate 230 by using the plastic encapsulation layer L, thereby avoiding leakage current or electrical breakdown between the second connection member 250 and the metal substrate 230, and ensuring electrical insulation between the metal substrate 230 and the second connection member 250. A part of the second connection member 250 across the metal substrate 230 is sandwiched by the first layer L1 and the second layer L2, which can further reduce occurrence of the leakage current or the electrical breakdown between the second connection member 250 and the external environment, thereby improving an overall insulation effect, safety, and reliability of the chip packaging body 200.

In the above structure, the cross member 251 is disposed to be combined with the metal substrate 230, and the first surface of the metal substrate 230 is planar. Therefore, a vertical distance between the second connection member 250 and the metal substrate 230 that serves as another transmission network on a bottom of the chip 220 can be increased, reducing the occurrence of the leakage current or the electrical breakdown between the second connection member 250 and the metal substrate 230, and ensuring the electrical insulation between the metal substrate 230 and the second connection member 250. The second extension member 252 extends towards the edge on the first surface of the base circuit board 210, so as to free up the space in the first layer L1 and the second layer L2 above the second extension member 252 for routing the conductive trace 290. The signal of the edge of the first surface of the base circuit board 210 is vertically led to the edge of the side of the first layer L1 away from the base circuit board 210 through the second connection member 250, thereby facilitating external connection.

In some embodiments, thicknesses of the traces and connection members disposed on the first surface of the base circuit board 210 may be greater than or equal to 100 microns, so as to meet electrical conductivity requirements of various connection members and traces.

As illustrated in FIG. 4, FIG. 4 is an enlarged structural schematic view of a second connection member of FIG. 2.

In some embodiments, the cross member 251 includes a third connection hole 2511, a cross part 2512, and a fourth connection hole 2513 that are connected in sequence. Each connection hole in the present embodiment is a metalized hole with electrical conductivity.

The third connection hole 2511 and the fourth connection hole 2513 are defined in the second layer L2, and the cross part 2512 is attached to the side of the second layer L2 away from the base circuit board 210. An end of the third connection hole 2511 is connected to the first surface of the chip 220, another end of the third connection hole 2511 is connected to an end of the cross part 2512, another end of the cross part 2512 is connected to an end of the fourth connection hole 2513, and another end of the fourth connection hole 2513 is connected to an end of the second extension member 252 on the first surface of the base circuit board 210.

The third connection hole 2511, the cross part 2512, and the fourth connection hole 2513 form a bridge structure. The cross member 251 is first led up to the second layer L2 through the third connection hole 2511, crossed over the metal substrate 230, and then lowered to the first surface of the base circuit board 210, thereby increasing the distance upwards. The metal substrate 230 is disposed in the mounting through-groove 211, so as to increase the distance downwards. Therefore, it can achieve a two-fold increase in the distance between the second connection member 250 and the metal substrate 230.

The second vertical member 253 includes a fifth connection hole 2531 and a sixth connection hole 2532 that are connected in sequence. The fifth connection hole 2531 is defined in the second layer L2, and the sixth connection hole 2532 is defined in the first layer L1. An end of the fifth connection hole 2531 is connected to the another end of the second extension member 252, and an end of the sixth connection hole 2532 away from the fifth connection hole 2531 is exposed on the first surface of the plastic encapsulation layer L. The fifth connection hole 2531 and the sixth connection hole 2532 form a vertically stacked-hole, which leads the signal upwards. In order to prevent external leakage current of the second connection member 250, sufficient thickness of the plastic encapsulation layer L on the first surface of the base circuit board 210 needs to be set. If the first layer L1 and the second layer L2 are laminated in the single pressing, the second vertical member 253 cannot be completely filled by electroplating due to excessive thickness in the single pressing. Therefore, the dual-setting of the first layer L1 and the second layer L2, and the double stacked-hole design corresponding to the second vertical member 253, are adopted to simultaneously ensure the thickness of the plastic encapsulation layer L on the first surface of the base circuit board 210 and the electrical conductivity of the second vertical member 253.

In some embodiments, the first surface of the chip 220 is provided with a gate electrode 221 and a transmission electrode, and the second surface of the chip 220 is provided with another transmission electrode. The metal substrate 230 is connected to the transmission electrode on the second surface of the chip 220, and the first connection member 270 is connected to the second surface of the metal substrate 230. Therefore, the signal of the transmission electrode on the second surface of the chip 220 is led out through the metal substrate 230 and the first connection member 270 to the plastic encapsulation layer for exposure, thereby facilitating connection of the external device.

The chip 220 includes the power chip, such as the insulated gate bipolar transistor (IGBT chip) or the metal-oxide semiconductor field-effect transistor (MOSFET chip).

The transmission electrode (not illustrated in figures) includes a current input stage and a current output stage. In a case where the chip 220 is the insulated gate bipolar transistor, the transmission electrode may be an emitter or a collector. In a case where the chip 220 is the metal-oxide semiconductor field-effect transistor, the transmission electrode may be a source electrode or a drain electrode. Specific types of one transmission electrode connected to the second connection member 250 and another transmission electrode connected to the metal substrate 230 may be arbitrarily set or exchanged based on a type of the chip and actual needs, which are not limited here. In some embodiments, in a case where the chip 220 is the metal-oxide semiconductor field-effect transistor, an electrode connected to the second connection member 250 may be the source electrode, and an electrode connected to the metal substrate 230 may be the drain electrode; or, the electrode connected to the second connection member 250 may be the drain electrode, and the electrode connected to the metal substrate 230 may be the source electrode.

As illustrated in FIG. 2, in some embodiments, the chip packaging body 200 further includes a third connection member 280. An end of the third connection member 280 is connected to the gate electrode 221 of the first surface of the chip 220, and another end of the third connection member 280 passes through the plastic encapsulation layer L and is exposed on the first surface of the plastic encapsulation layer L.

In some embodiments, the third connection member 280 may include a ninth connection hole 281 and a tenth connection hole 282 that are stacked. An end of the ninth connection hole 281 is connected to the gate electrode 221 on the first surface of the chip 220, and an end of the tenth connection hole 282 away from the ninth connection hole 281 is exposed on the first layer L1.

In some embodiments, the third connection member 280 may include a metal base, the metal base is inserted into the first layer L1 and the second layer L2, so that the metal substrate is connected to the gate electrode 221 of the chip 220. A specific structure of the third connection member 280 is not limited here.

The third connection member 280 may also extend to the board edge area of the first layer L1 after the third connection member 280 is exposed on the first layer L1, so that the external structure is connected.

In some embodiments, the chip packaging body 200 further includes the conductive trace 290. The conductive trace 290 is fundamental wiring on the chip packaging body 200 that is configured to implement electrical functions. The conductive trace 290 is a low-voltage connection network.

A layout area of the conductive trace 290 includes one or more selected from the group consisting of the surface of the second layer L2 away from the base circuit board 210, the surface of the first layer L1 away from the base circuit board 210, and the first surface of the base circuit board 210. The specific setting of the layout area of the conductive trace 290 is based on actual needs.

The conductive trace 290 may be connected to the third connection member 280. The third connection member 280 is connected to the gate electrode 221 of the chip 220 and belongs to the low-voltage connection network. Therefore, the conductive trace 290 may be connected to the third connection member 280. However, both the first connection member 270 and the second connection member 250 are connected to the transmission electrode of the chip 220 and belong to a high-voltage connection network. Therefore, both the first connection member 270 and the second connection member 250 need to be insulated from the conductive trace 290. That is, distances between the conductive trace 290 and other connection members should be greater than 0.3 millimeters, so as to standardize a minimum distance between different connection networks of the chip packaging body 200, thereby ensuring the electrical insulation between the connection networks.

In some embodiments, a distance among different connection networks may include but is not limited to 0.3 millimeters, 0.4 millimeters, 0.5 millimeters, 0.8 millimeters, 1.0 millimeters, 2.0 millimeters, or 3.0 millimeters, etc.

A thickness of the base circuit board 210, a distance between each connection member and the metal substrate 230, and a distance between a lateral wiring area of the connection member connected to the transmission electrode of the chip 220 and the external environment may all be greater than 0.3 millimeters, so as to further improve the internal electrical insulation effect of the chip packaging body 200.

In some embodiments, the chip packaging body 200 further includes a heat dissipation device 267. The heat dissipation device 267 is attached to the second surface of the base circuit board 210, and the second surface of the base circuit board 210 is a surface that is opposite to the first surface of the base circuit board 210. The second surface of the metal substrate 230, the second surface of the base circuit board 210, and the second surface of the chip 220 are all located on the same side.

The heat dissipation device 267 includes an insulation plate 260 and a heat sink 264. The insulation plate 260 is fixed and attached to the second surface of the base circuit board 210, and the heat sink 264 is fixed and attached to a surface of the insulation plate 260 away from the base circuit board 210.

The heat dissipation device 267 of the present embodiment may be obtained by welding the insulation plate 260 onto the heat sink 264. The welding may include tin reflow welding, silver sintering, etc. The heat sink 264 includes a metal heat sink, an air-cooled heat sink, or a liquid-cooled heat sink.

In some embodiments, the heat sink 264 may include a protruding heat dissipation structure 266 and a main body plate 265. The main body plate 265 is fixed and attached to the second surface of the insulation plate 260 away from the base circuit board 210. The protruding heat dissipation structure 266 is fixedly disposed on a surface of the main body plate 265 away from the insulation plate 260. A shape of the protruding heat dissipation structure 266 may include, but is not limited to, one or more selected from the group consisting of columnar-type, corrugated-type, series-connected-plate-type, and finned-type, etc. A material of the heat sink 264 may include, but is not limited to, copper, aluminum, stainless steel, etc. The heat sink 264 may be the metal heat sink, the air-cooled heat sink, or the liquid-cooled heat sink, etc., which is not specifically limited here.

The insulation plate 260 is fixed and attached to the second surface of the base circuit board 210, the insulation protection can be achieved on the second surface of the base circuit board 210 using the insulation plate 260, preventing leakage current from the second surface of the base circuit board 210 to the heat sink 264 or the external environment.

In some embodiments, the insulation plate 260 includes a first metal layer 261, an insulation layer 263, and a second metal layer 262 that are stacked and attached in sequence. The first metal layer 261 is also attached to the second surface of the base circuit board 210, and the second metal layer 262 is also attached to a surface of the heat sink 264 close to the metal substrate 230. In a case where the first metal layer 261 is attached to the second surface of the base circuit board 210, the first metal layer 261 may also be attached to the first extension member 271.

The first metal layer 261 is configured to achieve welding fixation between the metal substrate 230 and the insulation layer 263, and the second metal layer 262 is configured to achieve welding fixation between the insulation layer 263 and the heat sink 264. The position fixing of the insulation layer 263 and the heat sink 264 is achieved through the above-mentioned stacked insulation plate 260.

The first metal layer 261 and the second metal layer 262 may be attached and fixed by direct bonding or welding.

A thickness of each of the first metal layer 261 and the second metal layer 262 ranges from 0.01 millimeters to 1.00 millimeter. In some embodiments, the thickness of each of the first metal layer 261 and the second metal layer 262 is 0.05 millimeters, 0.11 millimeters, 0.17 millimeters, 0.25 millimeters, 0.3 millimeters, 0.45 millimeters, 0.52 millimeters, 0.63 millimeters, 0.75 millimeters, 0.8 millimeters, 0.95 millimeters, or 1.00 millimeter, etc. The thickness of the first metal layer 261 and the thickness of the second metal layer 262 are the same or different. A material of each of the first metal layer 261 and the second metal layer 262 includes one or more selected from the group consisting of copper, aluminum, silver, titanium, tin, molybdenum, and tungsten.

The insulation plate component 260 of the present embodiment may be pre-prepared and then welded and fixed to the base circuit board 210, so as to independently achieve high-temperature welding between the first metal layer 261 and the insulation layer 263, as well as high-temperature welding between the second metal layer 262 and the insulation layer 263, thereby preventing the high temperature from affecting the reliability of the base circuit board 210.

In some embodiments, the first metal layer 261 is attached to the second surface of the base circuit board 210 and the second surface of the metal substrate 230.

A length of a connection path between a side surface of the first metal layer 261 and a side surface of the heat sink 264 is greater than 0.3 millimeters, and the side surface of the first metal layer 261 and the side surface of the heat sink 264 are located on the same side. Due to the connection between the first metal layer 261 and the metal substrate 230, the first metal layer 261 also belongs to the connection network. Therefore, the length of the connection path between the side surface of the first metal layer 261 and the side surface of the heat sink 264 is limited to be greater than 0.3 millimeters, and the side surface of the first metal layer 261 and the side surface of the heat sink 264 are located on the same side. That is, the sum of a distance between the side surface of the first metal layer 261 and the side surface of the insulation layer 263 and a thickness of the insulation layer 263 is greater than 0.3 millimeters, and the side surface of the first metal layer 261 and the side surface of the insulation layer 263 are located on the same side. This distance limitation may be achieved by inwardly shrinking the first metal layer 261. An area where the first metal layer 261 shrinks is filled with the plastic encapsulation material of the base circuit board 210.

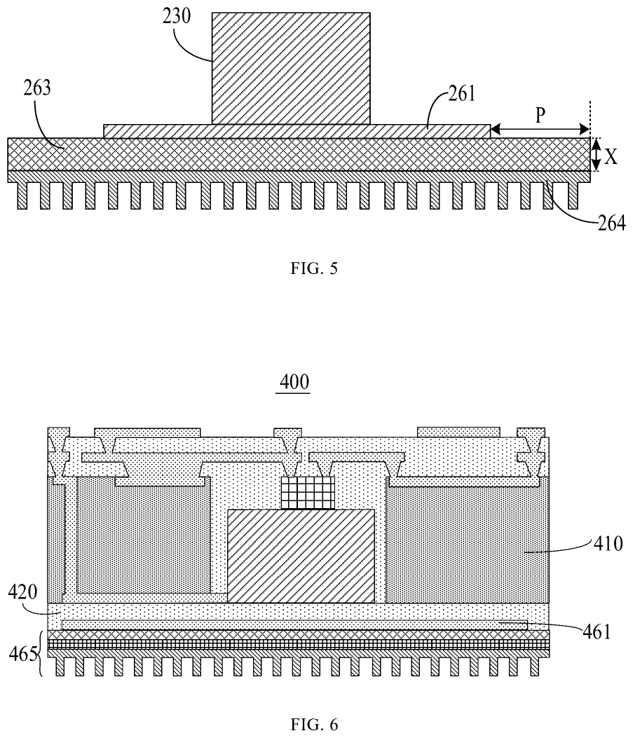

As illustrated in FIG. 5, FIG. 5 is a structural schematic view illustrating a partial structure between a metal substrate and a heat sink.

A side surface connection path S between the metal substrate 230 and the heat sink 264 is composed of a distance between an edge of the connection network where the metal substrate 230 is located and an edge of the insulation layer 263, as well as a thickness X of the insulation layer 263. The edge of the connection network where the metal substrate 230 is located and the edge of the insulation layer 263 are located on the same side. That is, S=P+X. A minimum length of a path that the current may break down needs to be greater than 0.3 millimeters, so as to prevent electrical breakdown and improve the external insulation effect on the metal substrate 230.

The side surface connection path P in the present embodiment may be a distance between the edge of the first metal layer 261 and the edge of the insulation layer 263, and the edge of the first metal layer 261 and the edge of the insulation layer 263 are located on the same side. The edge of the first extension member 271 does not protrude from the corresponding edge of the first metal layer 261. The same applies to the third extension member 553 in FIG. 8.

In the structure of the above chip packaging body 200, the first metal layer 261 is configured to achieve fixation between the metal substrate 230 and the insulation layer 263, and the second metal layer 262 is configured to achieve fixation between the insulation layer 263 and the heat sink 264. The setting of the metal substrate 230 can also improve the heat dissipation efficiency of the chip packaging body 200.

In some embodiments, the insulation layer 263 of the insulation plate 260 includes a ceramic layer and/or a resin layer.

In a case where the insulation layer 263 is the ceramic layer, a thickness of the ceramic layer is greater than 0.05 millimeters. In some embodiments, the thickness of the ceramic layer is 0.05 millimeters, 0.10 millimeters, 0.16 millimeters, 0.25 millimeters, 0.32 millimeters, 0.45 millimeters, 0.52 millimeters, 0.68 millimeters, 0.71 millimeters, 0.8 millimeters, 0.95 millimeters, or 1.00 millimeter, etc. The insulation layer 263 within this range can achieve insulation protection for a bottom of the base circuit board 210.

A material of the insulation layer 263 may be one or more selected from the group consisting of aluminum oxide, silicon nitride, aluminum nitride, beryllium oxide, diamond, etc. On the premise of achieving insulation protection, the above-mentioned ceramic materials can also ensure the thermal conductivity of the insulation layer 263, reaching 80 W/mK or even 1200 W/mK. This performance significantly exceeds the capabilities of materials such as silicone grease and resin, achieving a significant improvement in heat dissipation efficiency.

In some embodiments, in a case where the insulation layer 263 is the ceramic layer, the first metal layer 261 is attached to the second surface of the metal substrate 230 and the first extension member 271 by welding using a welding layer (not illustrated in the figures). The welding layer may include a solder layer close to the first metal layer 261 and a welding auxiliary metal layer covering the second surface of the metal substrate 230 and the second surface of the base circuit board 210. A size of the ceramic layer is greater than that of the metal substrate 230, but not greater than that of the base circuit board 210.

In a case where the insulation layer 263 is the resin layer, a thickness of the resin layer is greater than 0.3 millimeters. In some embodiments, the thickness of the resin layer includes but is not limited to 0.3 millimeters, 0.5 millimeters, 0.6 millimeters, 0.8 millimeters, 1.0 millimeter, or 1.5 millimeters, etc.

The resin layer includes but is not limited to one or more insulating materials, such as a prepreg, an epoxy resin, polyethylene terephthalate (PET), the polyimide, the polyimide-based material, the polycarbonate (PC), the bismaleimide triazine (BT)-based material, the Ajinomoto build film (ABF), the FR4 resin, and the ceramic-based material, etc.

In some embodiments, in a case where the insulation layer 263 is the resin layer, the first metal layer 261 may be omitted, and the insulation layer 263 may be directly attached to the second surface of the metal substrate 230 through resin bonding.

As illustrated in FIG. 6, FIG. 6 is a structural schematic view of a third embodiment of the chip packaging body provided in the present disclosure.

In the chip packaging body 400 of the present embodiment, a laminated insulation layer 420 may be disposed between the base circuit board 410 and the heat dissipation device 465, so as to form symmetrical compression with the first layer and the second layer, alleviate the internal stress of the upper single area layer, and reduce product warping. In some embodiments, a thickness of the laminated insulation layer 420 may be the same as or close to the sum of the thickness of the first layer and the thickness of the second layer. In some embodiments, a surface of the laminated insulation layer 420 is attached to the second surface of the base circuit board 410, and another surface of the laminated insulation layer 420 is attached to the first metal layer 461.

Electrical circuits, heat dissipation components, or the like may also be disposed inside the laminated insulation layer 420, depending on actual needs. Other conductive traces may also be disposed on the second surface of the base circuit board 410.

The other features of the chip packaging body 400 in the present embodiment may be the same as those in the previous embodiments. For details, refer to the preceding description, which is not repeated.

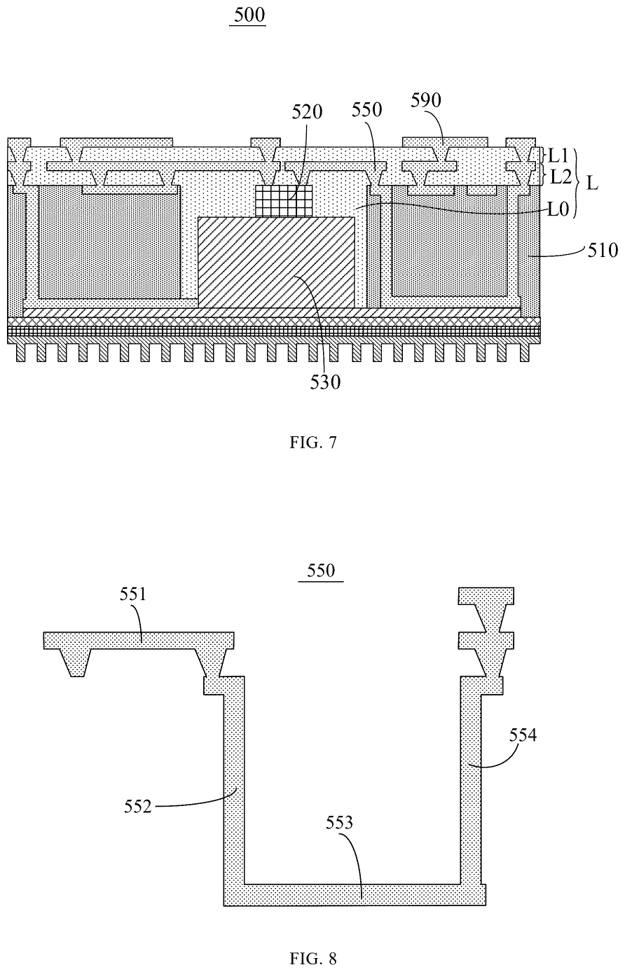

As illustrated in FIGS. 7-8, FIG. 7 is a structural schematic view of a fourth embodiment of the chip packaging body provided in the present disclosure, and FIG. 8 is an enlarged structural schematic view of the second connection member of FIG. 7.

In some embodiments, the second connection member 550 includes a cross member 551, a second conduction member 552, a third extension member 553, and a third vertical member 554 that are connected in sequence.

An end of the cross member 551 is connected to the first surface of the chip 520, and another end of the cross member 551 extends on the surface of the second layer away from the base circuit board 510 to reach the first surface of the base circuit board 510. A specific structure and a connection relationship of the cross member 551 are similar to those of the cross member 251 in the previous embodiments. For details, refer to the preceding description, which is not repeated.

The second conduction member 552 is disposed inside the base circuit board 510. An end of the second conduction member 552 is connected to another end of the cross member 551 on the first surface of the base circuit board 510, and another end of the second conduction member 552 vertically extends to the second surface of the base circuit board 510. The second conduction member 552 is a metalized hole inside the base circuit board 510, and the second conduction member 552 is configured to lead out the signal of cross member 551 downwards.

The third extension member 553 is disposed on the second surface of the base circuit board 510. An end of the third extension member 553 is connected to another end of the second conduction member 552, and another end of the third extension member 553 extends along the second surface of the base circuit board 510 to the board edge area.

The third vertical member 554 is disposed in the base circuit board 510, the second layer, and the first layer. An end of the third vertical member 554 is connected to another end of the third extension member 553 in the board edge area of the second surface of the base circuit board 510, and another end of the third vertical member 554 vertically extends to the surface of the first layer away from the second layer for exposure.

A structure of the third vertical member 554 is similar to that of the first vertical member 272 in the previous embodiments. For details, refer to the preceding description, which is not repeated.

In the present embodiment, the second conduction member 552, the third extension member 553, and the third vertical member 554 are sequentially disposed. The signal of the first surface of the chip 520 is led to the second surface of the base circuit board 510 through the second conduction member 552. Then, the signal is led from the second surface of the base circuit board 510 to the board edge area. Finally, the signal is led upwards to the first layer through the third vertical member 554 for exposure. Therefore, while the signal of the transmission electrode on the first surface of the chip 520 is led out, a relevant space on the first surface of the base circuit board 510 is freed up, so that a conductive trace 590 may be disposed in this part or this space. That is, the setting of the second connection member 550 in the present embodiment provides more wiring spaces for the conductive trace 590, while ensuring insulation distances between the second connection member 550 and other connecting networks.

The other features of the chip packaging body 500 in the present embodiment may be the same as those in the previous embodiments. For details, refer to the preceding description, which is not repeated.

Through the above structure, in the chip packaging body of some embodiments, one end of the first connection member is connected to the second surface of the metal substrate, so that the first connection member is connected to the chip. Another end of the first connection member extends along the second surface of the base circuit board to the board edge area, and then vertically extends to the surface of the plastic encapsulation layer away from the base circuit board for exposure. Therefore, while the electrode signal of the second surface of the chip is led out through the first connection member, the side of the first connection member close to the plastic encapsulation layer has a larger space for routing the conductive trace and increasing the insulation distances between the first connection member and other connection networks, thereby increasing the wiring flexibility of the chip packaging body. The present disclosure provides the connection structure that is compatible with the internal electrical insulation and wiring of the connection members of the chip packaging body, reserving or providing more space for routing other conductive traces and ensuring the wiring flexibility of the chip packaging body. In some embodiments of the present disclosure, the relevant space on the first surface of the base circuit board can be freed up by disposing the second connection member. The second connection member includes the cross member, the second conduction member, the third extension member, and the second vertical member that are connected in sequence. Therefore, the conductive traces can be disposed in this part or this space, thereby providing more space for routing the conductive traces and ensuring the insulation distances between the second connection member and other connecting networks. The present disclosure standardizes the shape of the metal substrate in assemblies and layout methods of various circuits, ensuring the electrical insulation of high-voltage circuits and avoiding the risk of electrical aging and insulation failure of the assemblies under high voltage and high switching frequency.

The above descriptions are only some embodiments of the present disclosure, and are not intended to limit the protection scope of the present disclosure. Any equivalent structure or equivalent flow transformation made by using the contents and the accompanying drawings of the present disclosure, or directly or indirectly applied to other related technical fields, is included in the protection scope of the present disclosure.

1. A chip packaging body, comprising:
a base circuit board, defining at least one mounting through-groove;
at least one chip unit, disposed in a corresponding mounting through-groove, wherein each chip unit comprises at least one metal substrate and at least one chip, each chip is connected to a first surface of a corresponding metal substrate, a second surface of the metal substrate is flush with a second surface of the base circuit board, and the second surface of the base circuit board is opposite to a first surface of the base circuit board;
a plastic encapsulation layer, disposed on the first surface of the base circuit board, wherein the plastic encapsulation layer completely fills a gap between the base circuit board and the at least one chip unit; and
a plurality of connection members, wherein an end of each connection member is connected to a corresponding electrode of the chip, and another end of each connection member extends to a first surface of the plastic encapsulation layer for exposure;
wherein the plurality of connection members comprise a first connection member, an end of the first connection member is connected to a side surface of the metal substrate, so that the first connection member is connected to the chip; and another end of the first connection member extends along the second surface of the base circuit board to a board edge area, and then vertically extends to a side of the plastic encapsulation layer away from the base circuit board for exposure.

2. The chip packaging body according to claim 1, wherein
the first connection member comprises a first extension member and a first vertical member that are connected in sequence;
an end of the first extension member is connected to the side surface of the metal substrate, and another end of the first extension member extends along the second surface of the base circuit board to the board edge area; and
the first vertical member is disposed in the board edge area, an end of the first vertical member is connected to the another end of the first extension member, and another end of the first vertical member vertically extends to the side of the plastic encapsulation layer away from the base circuit board for exposure.

3. The chip packaging body according to claim 2, wherein the plastic encapsulation layer comprises a filling layer, a first layer, and a second layer; the filling layer is disposed in the mounting through-groove; and the second layer is disposed on the first surface of the base circuit board, and the first layer is disposed on a surface of the second layer away from the base circuit board.

4. The chip packaging body according to claim 3, wherein
the first vertical member comprises a first conduction member, a second connection hole, and a first connection hole that are connected in sequence;
the first conduction member is disposed in the base circuit board, the first connection hole is disposed in the first layer, and the second connection hole is disposed in the second layer;
an end of the first conduction member is connected to the another end of the first extension member, another end of the first conduction member is connected to an end of the second connection hole, and an end of the first connection hole away from the second connection hole is exposed on a side of the first layer away from the base circuit board.

5. The chip packaging body according to claim 4, wherein
the second connection hole is connected to the first conduction member in a staggered manner, and a displacement member is connected to an end of the second connection hole away from the first layer and an end of the first conduction member away from the first extension member.

6. The chip packaging body according to claim 3, wherein the plurality of connection members further comprise a second connection member;
the second connection member comprises a cross member, a second extension member, and a second vertical member that are connected in sequence;
an end of the cross member is connected to a first surface of the chip, and another end of the cross member extends on the surface of the second layer away from the base circuit board to reach the first surface of the base circuit board;
an end of the second extension member is connected to the another end of the cross member, and another end of the second extension member extends along the first surface of the base circuit board to the board edge area; and
the second vertical member is disposed in the plastic encapsulation layer and disposed in the board edge area, an end of the second vertical member is connected to the another end of the second extension member, and another end of the second vertical member passes through the second layer and the first layer, until the another end of the second vertical member is exposed on the first surface of the plastic encapsulation layer.

7. The chip packaging body according to claim 3, wherein the plurality of connection members further comprise a second connection member;
the second connection member comprises a cross member, a second conduction member, a third extension member, and a third vertical member that are connected in sequence;
an end of the cross member is connected to a first surface of the chip, and another end of the cross member extends on the surface of the second layer away from the base circuit board to reach the first surface of the base circuit board;
the second conduction member is disposed in the base circuit board, an end of the second conduction member is connected to the another end of the cross member on the first surface of the base circuit board, and another end of the second conduction member vertically extends to the second surface of the base circuit board;
the third extension member is disposed on the second surface of the base circuit board, an end of the third extension member is connected to the another end of the second conduction member, and another end of the third extension member extends along the second surface of the base circuit board to the board edge area; and
the third vertical member is disposed in the base circuit board, the second layer, and the first layer, an end of the third vertical member is connected to the another end of the third extension member in the board edge area of the second surface of the base circuit board, and another end of the third vertical member vertically extends to a side of the first layer away from the second layer for exposure.

8. The chip packaging body according to claim 3, wherein the plurality of connection members further comprise a third connection member; and
the third connection member is disposed in the first layer and the second layer, an end of the third connection member is connected to a first surface of the chip, and another end of the third connection member is exposed on a side of the first layer away from the second layer.

9. The chip packaging body according to claim 8, wherein the third connection member comprises a ninth connection hole and a tenth connection hole that are stacked, an end of the ninth connection hole is connected to a gate electrode on the first surface of the chip, and an end of the tenth connection hole away from the ninth connection hole is exposed on the first layer.

10. The chip packaging body according to claim 8, wherein the chip packaging body further comprises a conductive trace;
a layout area of the conductive trace comprises one or more selected from the group consisting of the surface of the second layer away from the base circuit board, a surface of the first layer away from the base circuit board, and the first surface of the base circuit board; and
the conductive trace is connected to the third connection member, and a distance between the conductive trace and each of other connection members is greater than 0.3 millimeters.

11. The chip packaging body according to claim 1, wherein the chip packaging body further comprises:
a heat dissipation device, disposed on the second surface of the base circuit board, wherein the heat dissipation device comprises an insulation plate and a heat sink; the insulation plate is disposed on the second surface of the base circuit board, and the heat sink is disposed on a surface of the insulation plate away from the base circuit board.

12. The chip packaging body according to claim 11, wherein the heat sink comprises a protruding heat dissipation structure and a main body plate, the main body plate is disposed on a surface of the insulation plate away from the second surface of the base circuit board, and the protruding heat dissipation structure is disposed on a surface of the main body plate away from the insulation plate.

13. The chip packaging body according to claim 12, wherein
a shape of the protruding heat dissipation structure is one or more selected from the group consisting of columnar-type, corrugated-type, series-connected-plate-type, and finned-type.

14. The chip packaging body according to claim 11, wherein
the insulation plate comprises a first metal layer, an insulation layer, and a second metal layer that are stacked in sequence; and the second metal layer is disposed on a surface of the heat sink close to the metal substrate;
the first metal layer is disposed on the second surface of the base circuit board and the second surface of the metal substrate; and
a length of a connection path between a side surface of the first metal layer and a side surface of the heat sink is greater than 0.3 millimeters.

15. The chip packaging body according to claim 14, wherein
a thickness of each of the first metal layer and the second metal layer ranges from 0.01 millimeters to 1.00 millimeter.

16. The chip packaging body according to claim 14, wherein
the insulation layer comprises a ceramic layer and/or a resin layer; and
the insulation layer is the ceramic layer, and a thickness of the ceramic layer is greater than 0.05 millimeters; or the insulation layer is the resin layer, and a thickness of the resin layer is greater than 0.3 millimeters.

17. The chip packaging body according to claim 1, wherein a thickness of each of a trace and the plurality of connection members disposed on the first surface of the base circuit board is greater than or equal to 100 microns.

18. A chip packaging body, comprising:
a base circuit board, defining at least one mounting through-groove;
at least one chip unit, disposed in a corresponding mounting through-groove, wherein each chip unit comprises at least one metal substrate and at least one chip, each chip is connected to a first surface of a corresponding metal substrate, a second surface of the metal substrate is flush with a second surface of the base circuit board, and the second surface of the base circuit board is opposite to a first surface of the base circuit board;
a plastic encapsulation layer, disposed on the first surface of the base circuit board; and
a plurality of connection members, wherein an end of each connection member is connected to a corresponding electrode of the chip, and another end of each connection member extends to a first surface of the plastic encapsulation layer for exposure;
wherein the plurality of connection members comprise a first connection member, an end of the first connection member is connected to a side surface of the metal substrate, so that the first connection member is connected to the chip; and another end of the first connection member extends along the second surface of the base circuit board to a board edge area, and then vertically extends to a side of the plastic encapsulation layer away from the base circuit board for exposure.

19. The chip packaging body according to claim 18, wherein
the first connection member comprises a first extension member and a first vertical member that are connected in sequence;
an end of the first extension member is connected to the side surface of the metal substrate, and another end of the first extension member extends along the second surface of the base circuit board to the board edge area; and
the first vertical member is disposed in the board edge area, an end of the first vertical member is connected to the another end of the first extension member, and another end of the first vertical member vertically extends to the side of the plastic encapsulation layer away from the base circuit board for exposure.

20. The chip packaging body according to claim 19, wherein the plastic encapsulation layer comprises a filling layer, a first layer, and a second layer; the filling layer is disposed in the mounting through-groove; and the second layer is disposed on the first surface of the base circuit board, and the first layer is disposed on a surface of the second layer away from the base circuit board.
